(19) United States
(12) Patent Application Publication
(10) Pub. No.: US 2013/0044419 A1
(43) Pub. Date: Feb. 21, 2013

(54) ELECTRONIC DEVICE

(71) Applicant: Masamichi WATANABE, Kawasaki-shi (JP)

(72) Inventor: Masamichi WATANABE, Kawasaki-shi (JP)

(73) Assignee: FUJITSU MOBILE COMMUNICATIONS LIMITED, Kawasaki-shi (JP)

(21) Appl. No.: 13/570,794

(22) Filed: Aug. 9, 2012

(30) Foreign Application Priority Data
Aug. 18, 2011 (JP) 2011-178739

(51) Int. Cl. H05K 7/00

(52) U.S. Cl. 361/679.01

(57) ABSTRACT

An electronic part is held in a sheet-metal part holder having a U-shaped cross-section. The part holder holds the electronic part between a first face and a second face thereof. A front casing corresponding to the first face and a rear casing corresponding to the second face each have an opening bored such that the first face or the second face is exposed through the opening. This enables the thicknesses of the casings to be reduced to that of the part holder.

### CROSS-REFERENCE TO RELATED APPLICATION

This application is based upon and claims the benefit of priority of the prior Japanese Patent Application No. 2011-178739, filed on Aug. 18, 2011, the entire contents of which are incorporated herein by reference.

### FIELD

The embodiments discussed herein are related to electronic devices.

### BACKGROUND

In electronic devices such as cellular phones and various mobile terminals, large electronic parts such as liquid-crystal displays are surrounded by sheet-metal members so as to be protected, and are held in the devices by casings of the devices pressed against the sheet-metal members (for example, see Japanese Laid-open Patent Publication No. 8-262992).

Electroacoustic transducers such as speakers, receivers, and microphones built in cellular phones and the like are electronic parts smaller than liquid-crystal displays, and are held in electronic devices without being protected by sheet-metal members (for example, see Japanese Laid-open Patent Publication No. 2010-087638). In the example described in Japanese Laid-open Patent Publication No. 2010-087638, an electronic part serving as a speaker is accommodated in a partitioned space formed by front and rear casings, and a sheet metal is interposed between the electronic part and the front casing so as to maintain a predetermined distance therebetween. The front casing has a hole for transmitting sound signals bored at a position opposing the electronic part. The hole emits sound waves radiated from the speaker to the outside, and guides sound signals from the outside of the device to a microphone.

Typical electronic devices hold electronic parts inside thereof by joining front and rear casings together. Therefore, the thickness of portions accommodating the electronic parts results in at least the sum of the thickness of the electronic parts, that of the front casings, and that of the rear casings. This prevents the electronic devices from being reduced in thickness.

### SUMMARY

According to an aspect of the embodiments, an electronic device includes an electronic part; a part holder having a first face and a second face that hold the electronic part therebetween; and a casing having an opening through which at least one of the first face and the second face of the part holder is exposed.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a partially enlarged cross-sectional view of a principal part of an electronic device according to a first embodiment;

FIG. 2 illustrates an electronic part and a part holder before the electronic part is installed in the part holder;

FIG. 3 illustrates the electronic part and the part holder after the electronic part is installed in the part holder;

FIG. 4 illustrates a rear casing before the part holder is attached thereto;

FIG. 5 illustrates the rear casing and the part holder after the part holder is attached to the rear casing;

FIG. 6 is a cross-sectional view taken along line a-a in FIG. 5; and

FIG. 7 is a cross-sectional view of a principal part of an electronic device according to a second embodiment.

### DESCRIPTION OF EMBODIMENTS

Embodiments of the present invention will now be described with reference to the drawings. The embodiments may be combined without deviating from the inventive concept.

### (a) First Embodiment

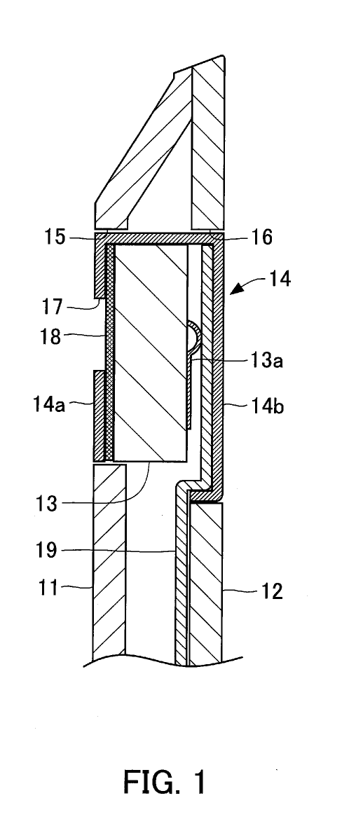

FIG. 1 is a partially enlarged cross-sectional view of a principal part of an electronic device according to a first embodiment;

The electronic device according to the first embodiment may be installed in apparatuses whose thickness needs to be reduced. Such apparatuses include, for example, cellular phones, smart phones, notebook personal computers, portable televisions, and electronic dictionaries. Herein, a speaker will be described as an example electronic part that may prevent a reduction in the thickness of an electronic device. However, such electronic parts are not limited to speakers, and may be other electroacoustic transducers such as buzzers and microphones or other functional parts such as liquid crystal panels and batteries.

The electronic device includes a front casing 11, a rear casing 12, and an electronic part 13 disposed inside a space enclosed by the casings 11 and 12. The electronic part 13 is held and accommodated in a part holder 14 having a U-shaped cross-section. The part holder 14 is formed by folding a thin sheet metal, and has a thickness substantially the same as that of the casings 11 and 12. The top surface of the part holder 14 is exposed through an opening 15 formed in the front casing 11, and the bottom surface of the part holder 14 is exposed through an opening 16 formed in the rear casing 12. That is, the thickness of the electronic device is reduced to the thickness of the folded part holder 14.

The part holder 14 has a hole 17 for acoustic transmission bored in a first face 14a exposed through the front casing 11. This hole emits sound waves radiated from the electronic part 13 to the outside. A dust-proof cloth 18 is disposed between the first face 14a of the part holder 14 and the electronic part 13. A flexible printed circuit board 19 is disposed between a second face 14b of the part holder 14 and the electronic part 13. The electronic part 13 is provided with a terminal 13a having a plate-spring shape, and the terminal 13a is pressed toward the flexible printed circuit board 19 when the electronic part 13 is installed in the part holder 14. As a result, the electronic part 13 is electrically connected to the flexible printed circuit board 19. The electrical connection between the terminal 13a having a spring contact structure and the flexible printed circuit board 19 is secured by the part holder 14 that surrounds the electronic part 13. This flexible printed circuit board 19 extends to the outside of the part holder 14, and is electrically connected to a driving circuit in a controller (not illustrated).

The part holder 14 is formed of a conductive sheet metal, and is connected to a ground terminal of the electronic device. The electronic part 13 is shielded by the part holder 14, and is not directly affected by, for example, static electricity or electromagnetic waves from the outside since the static electricity or electromagnetic waves are released into the ground. Since the part holder 14 surrounds the periphery of the electronic part 13, the electronic device is prevented from emitting noise to the outside if the electronic part 13 is a possible noise source that may cause electromagnetic interference.

A procedure for assembling the electronic device will now be described.

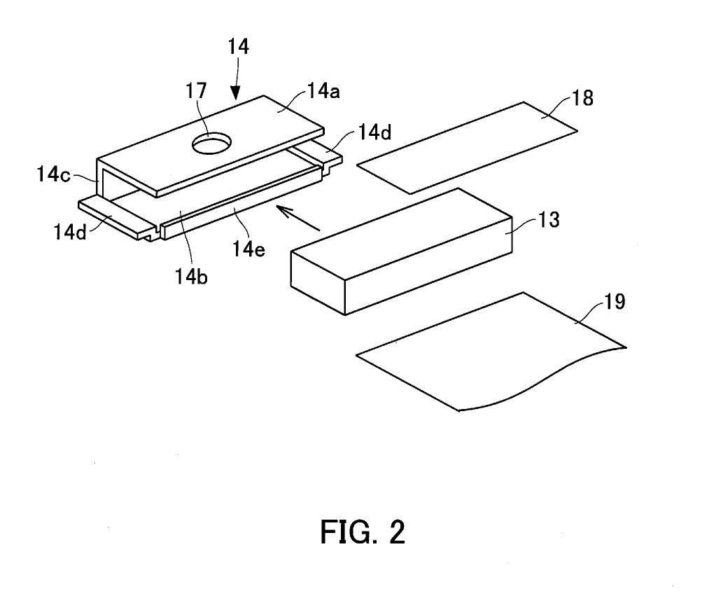

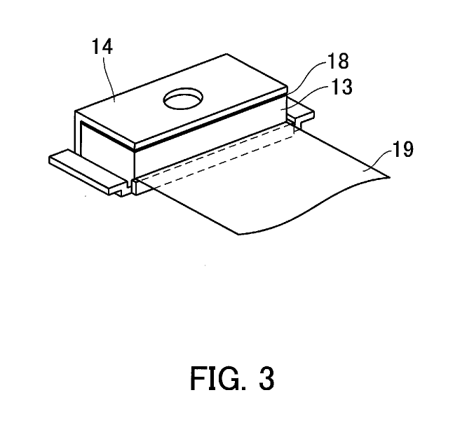

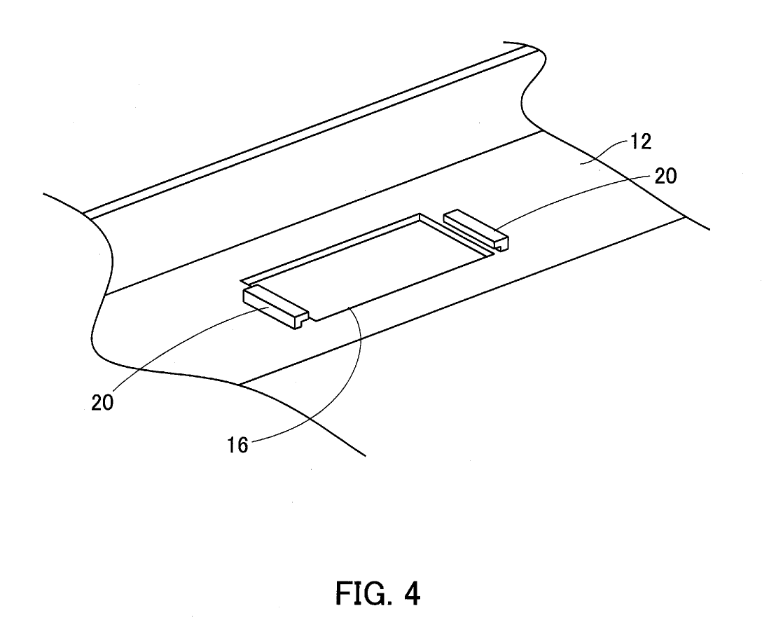

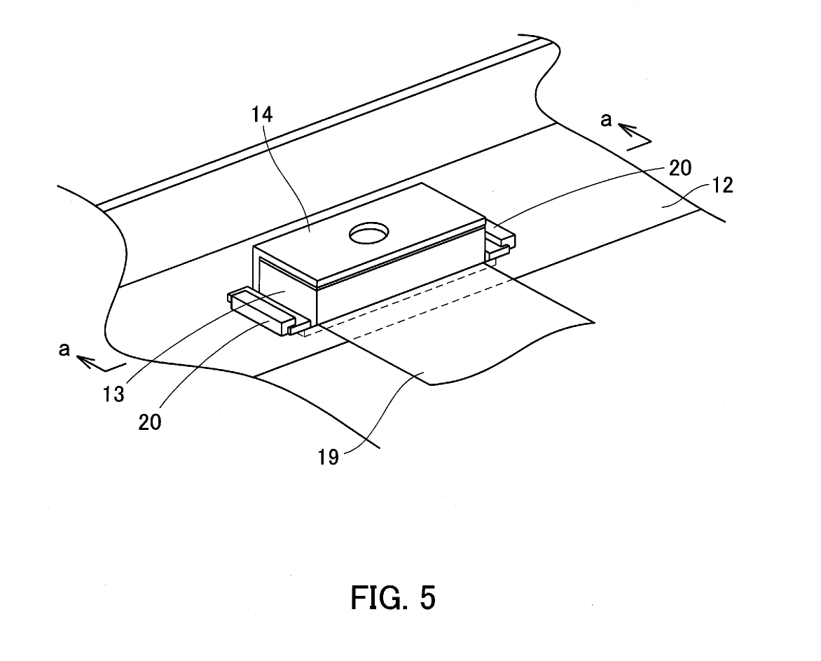

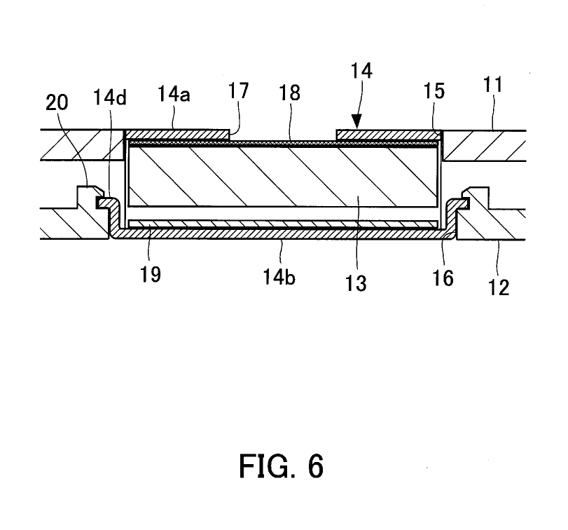

FIG. 2 illustrates the electronic part and the part holder before the electronic part is installed in the part holder, and FIG. 3 illustrates the electronic part and the part holder after the electronic part is installed in the part holder. FIG. 4 illustrates the rear casing before the part holder is attached thereto, and FIG. 5 illustrates the rear casing and the part holder after the part holder is attached to the rear casing. FIG. 6 is a cross-sectional view taken along line a-a in FIG. 5.

As illustrated in FIG. 2, the part holder 14 has the first face 14a, the second face 14b, and a connecting portion 14c. The first face 14a and the second face 14b are parallel to each other so as to hold the electronic part 13 from both sides of the electronic part 13, and the connecting portion 14c connects the first face 14a and the second face 14b so as to form a U-shaped cross-section. The first face 14a has the hole 17 for acoustic transmission bored in the central portion thereof. The second face 14b has engaging portions 14d at sides adjacent to the side to which the connecting portion 14c is connected. The engaging portions 14d engage with the rear casing 12. The engaging portions 14d extend from the sides of the second face 14b toward the first face 14a, and then are bent outward. The second face 14b further has a bent portion 14e at a side opposing that to which the connecting portion 14c is connected. The bent portion 14e extends toward the first face 14a. The second face 14b is increased in rigidity due to the connecting portion 14c, the engaging portions 14d, and the bent portion 14e formed at the four sides.

The electronic part 13, the dust-proof cloth 18, and the flexible printed circuit board 19 are accommodated in the part holder 14. For example, the electronic part 13 is installed in the part holder 14 by fitting the electronic part 13 into the part holder 14 while the electronic part 13 is held between the dust-proof cloth 18 and the flexible printed circuit board 19. Once the electronic part 13 is installed in the part holder 14, the terminal 13a having the spring contact structure fixes the electronic part 13 in the part holder 14. That is, the terminal 13a urges the electronic part 13 toward the first face 14a, and urges the flexible printed circuit board 19 toward the second face 14b. This enables the electronic part 13 to be held in the part holder 14, and as a result to be integrated with the part holder 14 as illustrated in FIG. 3. Since the terminal 13a of the electronic part 13 is in the part holder 14 and is not exposed to the outside in this state, the contact point is not brought into contact with any other parts or is not deformed due to such contact in the subsequent assembling steps.

As illustrated in FIG. 4, the rear casing 12 to which the part holder 14 is attached has the opening 16 which is of such a size that the second face 14b of the part holder 14 is fitted therein. In addition, the casing 12 has engaging portions 20 formed along the opposing short sides of the opening 16. These engaging portions 20 extend upward from the casing 12, and are bent towards the opening 16 at a height from the surface of the casing 12 corresponding to the thickness of the sheet-metal member of the part holder 14 so as to form L-shaped cross-sections.

As illustrated in FIGS. 5 and 6, the engaging portions 14d of the part holder 14 engage with the engaging portions 20 of the casing 12 when the part holder 14 is fitted in the opening 16 of the casing 12. With this, the part holder 14 is fixed to the casing 12 while the part holder 14 is partially fitted in the opening 16. In the example illustrated in FIG. 6, the outer surface of the second face 14b is flush with that of the casing 12. In addition, the outer surface of the first face 14a of the part holder 14 is flush with that of the casing 11 when the front casing 11 is assembled to the rear casing 12. As a result, the electronic device would be reduced in thickness if the electronic part 13 accommodated in the electronic device has a large dimension in the thickness direction of the electronic device compared with the case where the electronic part 13 is only held between the casings 11 and 12.

As described above, the electronic device includes the part holder 14 having the first face 14a and the second face 14b that hold the electronic part therebetween, the front casing 11 having the opening 15, and the rear casing 12 having the opening 16, at least one of the first face 14a and the second face 14b of the part holder 14 being exposed through the openings.

This enables the electronic device to be reduced in thickness at the portion where the casings 11 and 12 accommodate the electronic part 13. For example, the thickness of the electronic device formed as illustrated in FIG. 1 using the part holder having a sheet-metal member of a thickness of 0.3 mm is reduced by 1.3 mm compared with the case where the front casing 11 having a thickness of 1.0 mm and the rear casing 12 having a thickness of 0.9 hold the electronic part 13 therebetween.

### (b) Second Embodiment

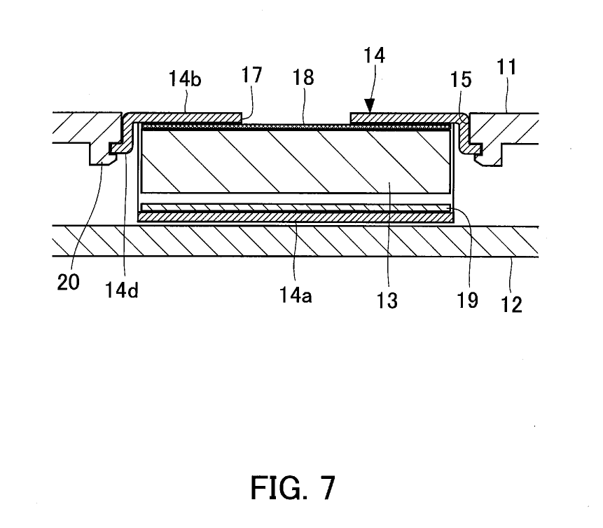

FIG. 7 is a cross-sectional view of a principal part of an electronic device according to a second embodiment. In FIG. 7, the same reference numbers and symbols are used for components the same as those in FIG. 6, and the detailed descriptions thereof will be omitted.

The electronic device according to the second embodiment has an opening in one of the casings 11 and 12, and the part holder 14 is fitted in the opening while the electronic device according to the first embodiment has the openings in both the casings 11 and 12. In the example illustrated in FIG. 7, the electronic device has the opening 15 in the front casing 11, and has the engaging portions 20 formed along the opposing sides of the opening 15. The engaging portions 14d of the part holder 14 engage with the engaging portions 20 to fix the part holder 14 to the front casing 11. The rear casing 12 has no opening corresponding to the opening 15 formed in the front casing 11.

This part holder 14 has the hole 17 for acoustic transmission bored in the central portion of the second face 14b. The part holder 14 accommodates the flexible printed circuit board 19, the electronic part 13, and the dust-proof cloth 18 laminated in this order between the first face 14a and the second face 14b.

As described above, the electronic device has the opening formed in one of the casings 11 and 12.

This enables the electronic device to be reduced in thickness at the portion where the casings 11 and 12 accommodate the electronic part 13 by the difference between the thickness of the sheet-metal member of the part holder 14 and that of the casing 11 or 12. For example, the thickness of the electronic device formed as illustrated in FIG. 7 using the part holder 14 having a sheet-metal member of a thickness of 0.3 mm is reduced by 0.7 mm in cases where the front casing 11 has a thickness of 1.0 mm.

The application of the above-described embodiments enables the electronic device to be reduced in thickness.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An electronic device comprising:
an electronic part;
a part holder having a first face and a second face that hold the electronic part therebetween; and
a casing having an opening through which at least one of the first face and the second face of the part holder is exposed.

2. The electronic device according to claim 1, wherein the part holder has a connecting portion that connects the first face and the second face such that the part holder has a U-shaped cross-section.

3. The electronic device according to claim 2, wherein
the part holder has first engaging portions formed at two sides adjacent to the side to which the connecting portion is connected,
the casing has second engaging portions formed at two sides of the opening so as to correspond to the first engaging portions, and
the first engaging portions and the second engaging portions engage with each other to fix the part holder to the casing.

4. The electronic device according to claim 1, wherein the electronic part has a terminal of a spring contact structure electrically connected to a flexible printed circuit board that is disposed between the electronic part and the first face or the second face of the part holder.

5. The electronic device according to claim 1, wherein the part holder is formed of a conductive sheet metal connected to a ground terminal of the electronic device.
